(19) United States
(12) Patent Application Publication
(10) Pub. No.: US 2004/0160845 A1
(43) Pub. Date: Aug. 19, 2004

(54) Method and apparatus to reduce access time in synchronous FIFOS with zero latency overhead

(75) Inventors: Kalyana Chakravarthy, Delhi (IN); Jayesh Verma, Delhi (IN)

Correspondence Address: SEED INTELLECTUAL PROPERTY LAW GROUP PLLC, 701 FIFTH AVENUE, SUITE 6300, SEATTLE, WA, 98104-7092, US

(73) Assignee: STMicoelectronics Pvt. Ltd., Uttar Pradesh (IN)

(21) Appl. No.: 10/697,958

(22) Filed: Oct. 30, 2003

(30) Foreign Application Priority Data
Oct. 31, 2002 (IN) 1098/DEL/2002

(51) Int. Cl. G11C 8/00

(52) U.S. Cl. 365/230.04

(57) ABSTRACT

The invention provides method and apparatus to reduce access time in synchronous FIFOs with zero latency overheads. The FIFO buffer includes a FIFO circuit capable of storing ‘n’ data words, each ‘m’ bits wide, having an ‘m’ bit wide data input terminal. Furthermore, the FIFO buffer includes a read data set selection circuit connected to the data output terminals of the FIFO circuit and having two data output terminals providing simultaneous access to a selected storage location at an odd address and an even address. An odd read pointer generating circuit provides the selection input to the data selection circuit for selecting data at an odd read address of the read data selection circuit, while an even read pointer generating circuit provides the input for selecting data at an even read address. A multiplexer coupled to each of the two data output terminals of the read data set selection circuit selects one of its outputs as the final output of the FIFO. A state controlling circuit coupled to the multiplexer controls the selection of the final output and this circuit also controls the selection input to the read data set selection circuit for selecting an odd read address and an even read address.

### BACKGROUND OF THE INVENTION

1. Field of the Invention

The present invention relates to First In First Out (FIFO) memory circuits and, more particularly, to providing a method and apparatus for reducing access time in FIFOs with zero latency overhead.

2. Description of the Related Art

Many electronic designs incorporate First In First Out (FIFO) memory circuits as high-speed data buffers. In the majority of these applications the access time and latency of the FIFO are critical to the operation of the application. For this reason, it is desirable to have FIFOs that provide minimum latency and access time.

U.S. Pat. No. 5,388,074 describes a FIFO memory using a single output register. Although the method and apparatus put forth in the patent specification is simple, it has the disadvantage of introducing a latency of one read cycle during memory access. This latency is not acceptable in applications that are latency critical.

U.S. Pat. No. 6,067,267 describes a four-way interleaved FIFO architecture with look-ahead conditional decoder for PCI applications. This architecture suffers from the drawback that the arrangement of registers in the memory banks as proposed by it is more suitable to a particular type of application, for example PCI. The architecture is not scalable to other kind of memory architectures.

### BRIEF SUMMARY OF THE INVENTION

The disclosed embodiments of the invention overcome the above drawbacks in the prior art and provide a method and apparatus for reducing access time in FIFOs without introducing any latency overhead.

A method and apparatus is provided for reducing access time without latency overhead that is extendable to existing memories without significant modification in the basic architecture of the memories.

The invention provides a method and apparatus for reducing memory access time that is portable to different technologies.

In accordance with one implementation of the invention, a method and apparatus to reduce access time in synchronous FIFOs with zero latency overheads is provided. The improved FIFO buffer comprises FIFO means capable of storing ‘n’ data words, each ‘m’ bits wide, having an ‘m’ bit wide data input terminal. The FIFO means have two sets of data output terminals, each providing simultaneous access to half the number of storage locations, one set connected to the storage locations at odd addresses and the other connected to storage locations at even addresses. The output of the FIFO means is connected to a data selection means. The data selection means selects two data outputs corresponding to the value of the addresses on its selection buses. Odd read pointer generating means provides an address to one selection bus, while even read pointer generation means provides address to other selection bus. The two outputs of data selection means are coupled to a multiplexing means. A state controlling means controls the output of the multiplexing means, and it also controls odd read pointer means and even read pointer means.

In accordance with another embodiment of the invention, a FIFO buffer circuit is provided that is configured to reduce the overall access time by providing a method of look-ahead reading that is implemented by fetching the next word from the FIFO and assigning it to one of a first and second data out bus, the contents of which are not used at the current instant. This architecture provides a timing advantage of two read clock cycles for reading data from the FIFO. Ideally, the FIFO includes a state machine that is implemented using a single D-flip-flop such that the time required for word access is only the CP to Q delay of the flip-flop in the state machine plus the multiplexer delay.

In accordance with another embodiment of the invention, a method for reducing the access time of a FIFO buffer is provided, the method includes providing a FIFO capable of storing n data words, each n data word configured to be m bits wide, having an m bit wide data input terminal; connecting a read data selector to an output of the FIFO and providing simultaneous access to a selected storage location at an odd address and a selected storage location at an even address; providing selection inputs to the read data selector for selecting an odd read address and an even read address; multiplexing the output of the read data selector to enable selection of a desired one of the outputs of the read data selector as the final output of the FIFO; and controlling the state of the FIFO to select one of the multiplexer output as the final output of the FIFO and to control the selection input to the read data selector for selecting an odd read address and an even read address.

### BRIEF DESCRIPTION OF THE DRAWINGS

The disclosed embodiments of the present invention will become more understood with reference to the following description and accompanying drawings, wherein:

FIG. 1 shows a conventional circuit arrangement of FIFO memory using single output register;

FIG. 2 shows a conventional circuit arrangement of a four-way interleaved FIFO architecture with look-ahead conditional decoder for PCI applications;

FIG. 3 shows a circuit arrangement in accordance with the present invention; and

FIG. 4 shows a timing diagram illustrating the operation of the circuit arrangement of the present invention.

### DETAILED DESCRIPTION OF THE INVENTION

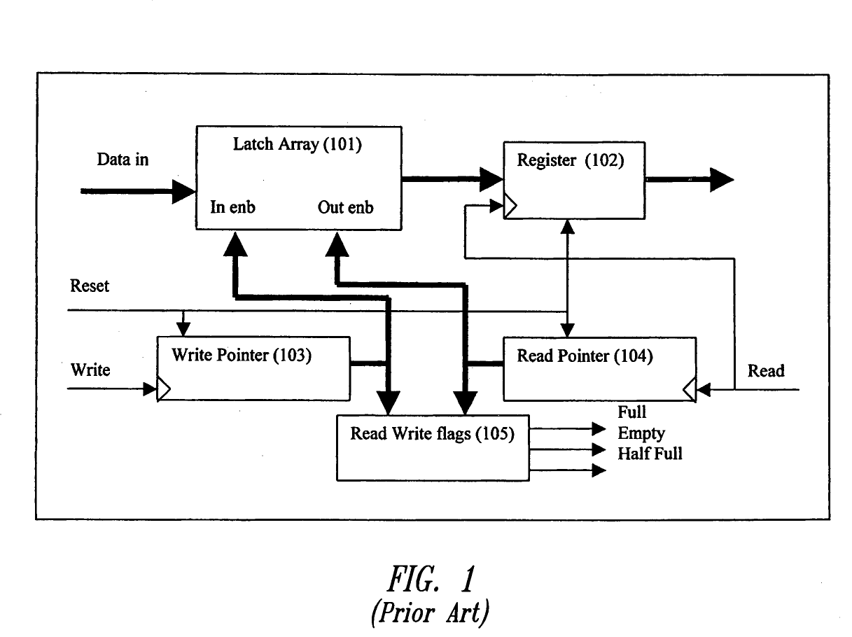

FIG. 1 shows a conventional circuit arrangement of FIFO memory using a single output register as described in patent U.S. Pat. No. 5,388,074. The system consists of a memory latch array 101, a write pointer logic circuit 103, a read pointer logic circuit 104 and a flag generation circuit 105. In addition, register 102 provides for increasing the speed of operation of the system. Latch array 101 consists of an array of n-bit latches in which the data is stored when the write pointer logic circuit 103 receives a “write” signal. The write pointers or the address signals pointing to a location in the latch array 101 are provided by the write pointer logic circuit on one branch of the signal bus going to the “In enb” pin of the latch array 101 to select the latch into which the data is to be stored by the write pointer logic circuit 103. The signal bus also goes to Read Write Flags 105 to generate full, empty, and half full flags.

Similarly, Read pointers or the address signals pointing to the latch array 101 location to be read are provided by the read pointer logic circuit 104 on one branch of the signal array going to the “Out enb” pin of the latch array 101. The signal bus also goes. to Read Write flags 105 to generate full, empty, and half-full flags.

The register 102 is an n-bit wide register array, which receives input from the output of latch array 101. The register array 102 is clocked by the Read signal. The access time obtained at the output of the system is the small clock to output (cp to Q) delay of the flip-flop.

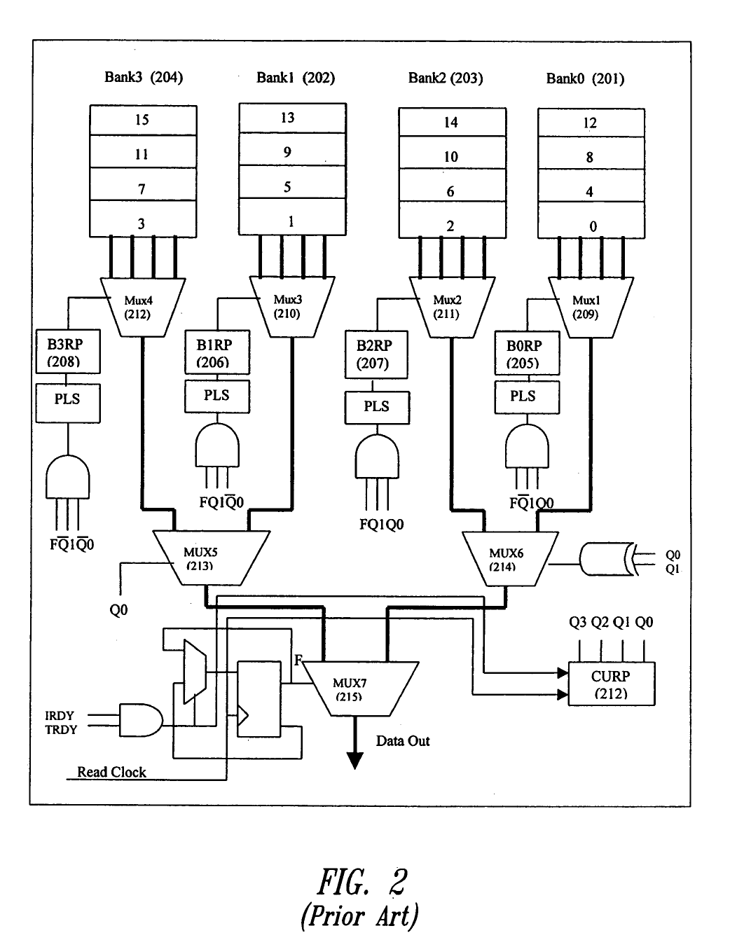

FIG. 2 shows a conventional circuit arrangement for a four-way interleaved FIFO architecture with look-ahead conditional decoder for PCI applications as described in U.S. Pat. No. 6,067,267. The architecture consists of four subarrays each of four 32-bit registers banks Bank0 201, Bank1 202, Bank2 203, and Bank3 204. The subarray comprising Bank3 204, which includes registers 3,7,11,15, and Bank1 202, which includes registers 1,5,9,13, is called the “Odd subarray” while the subarray comprising Bank2 203 which includes registers 2,6,10,14 and Bank0 201 which includes registers 0,4,8,12 is called the “Even subarray”. The output of each of these subarrays is connected to an independent 4:1 multiplexer. In other words, Bank3 204 is connected to Mux4 212, Bank2 203 to Mux2 211, Bank1 201 to Mux3 210 and Bank0 201 to Mux1 209. The output of Mux4 212 and Mux3 210 is further connected to a 2:1 multiplexer Mux5 213, while the output of Mux2 211 and Mux1 209 is connected to Mux6 214. Finally the output of Mux5 213 and Mux6 214 is multiplexed by another 2:1 multiplexer Mux7 215 whose output is the final data out. A 4-bit (Q3Q2Q1Q0) current pointer CURP 212 (a 4 bit binary counter with Trdylrdy) as count enable, points to the location to be read. It is initially set to “0000”. At a clock edge when Trdylrdy goes high, the 32-bit data corresponding to register 0 is supplied as data out. As long as the Trdylrdy is high, CURP increments at each clock edge.

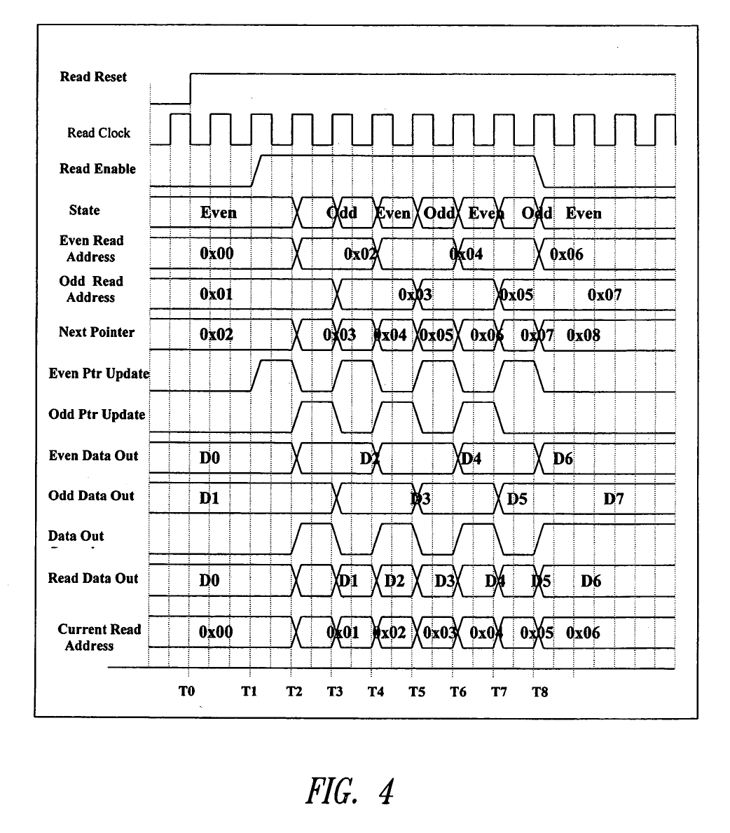

Each bank read pointer B0RP 205, B1RP 206, B2RP 207, B3RP 208 increments to the next four registers of its associated bank, once every four clock cycles. Each bank read pointer B0RP 205, B1RP 206, B2RP 207, B3RP 208 increments at one value of the two-bit combination Q1Q0. For example, the incrementing of the two bit bank “0” read pointer B0RP 205 is triggered by a signal from “PLS” generator when Q1Q0=“01”, that of the bank “1” read pointer B1RP 206 at Q1Q0=“10”, bank “2” read pointer B2RP 207 at Q1Q0=“11” and bank “3” read pointer B3RP 208 at Q1Q0=“00”. The flip-flop output “F” is the Q0 output shown in FIG. 4A and is controlled by the Trdylrdy signal. “F” or “Q0”, is high whenever any of the AND gates triggers a PLS generator to supply a signal to its associated bank read pointer 205, 206, 207, 208 to increment, when the decoder is also enabled to supply its output. The flip-flop output “F” is part of external circuitry connected to the FIFO.

A two-bit bank read pointer selects (through Mux4 212, Mux3 210, Mux2 211, Mux1 209) which register of each bank is to be read. Bank 0 read pointer B0RP 205, first selects one of the four 32-bit registers of Bank0 201, for example, register 0. Similarly B1RP 206 first selects register 1 of Bank1 202, B2RP 207 first selects register 2 of Bank2 203 and B3RP 208 first selects register 3 of Bank3 204. Each of the four bank read pointers increment after 4 clock cycles, and points to the next register in its bank. Therefore data is held for 4 clock cycles at the output of each bank.

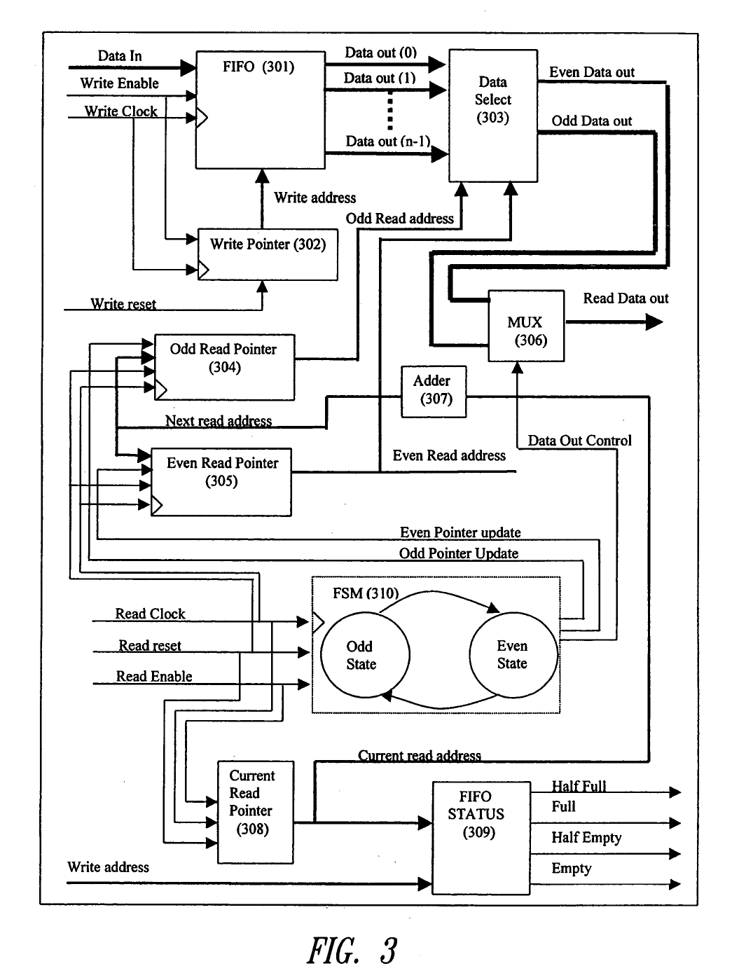

FIG. 3 shows a circuit arrangement in accordance with one embodiment of the present invention to overcome the disadvantages of the aforementioned conventional circuit arrangements. The system provided by the invention consists of a FIFO 301, which comprises an array of memory elements ‘m’ bits wide and ‘n’ bits deep. The ‘m’ bit wide data to be written into the FIFO is available on the ‘Data In’ bus. The write address bus points to the location in the FIFO into which the data is to be written. The write pointer circuit 302 generates the write address that is put on the Write address bus. The write address bus is ‘k’ bits wide, such that n=2^{k}. The contents of the ‘Data In’ bus are transferred into the FIFO element whose address is specified by the write address bus, when the write enable is at logic ‘1’ and a rising edge occurs on the write clock. The write pointer is reset by setting the write address bus to zero when the write reset signal is active. The contents of the write address bus are incremented when the write reset is inactive, write enable is active and a rising edge occurs on write clock.

The data from individual FIFO elements is available on ‘n’ ‘m’ bit wide data buses from ‘Data out (0)’ to ‘‘Data out (n−1)’. All the ‘n’ Data out buses are connected to the Data select circuit 303. The Data Select circuit 303 has two output ports “Even Data Out” and “Odd Data Out”. The “Even Data Out” bus contains the ‘Data out’ bus corresponding to the ‘Even read address’ while the “Odd data but” selects the data out bus corresponding to the ‘Odd read address’. The “Even Data out” and “Odd Data out” from the ‘Data Select’ 303 are connected to ‘MUX’ 306, which assigns one of the inputs to the “Read Data out” bus. The “Data Out Control” pin from the FSM 307 controls ‘MUX’ 306. The contents of “Even Data out” are assigned to “Data out” when the “Data out control” is at logic ‘0’, while contents of “Odd Data Out” are assigned to “Data out” when the “Data out control” is at logic ‘1’. ‘Odd Read Pointer’ 304 and ‘Even Read Pointer’ 305 circuits generate the “Odd Read Address” and “Even Read Address” buses respectively. The ‘Odd Read Pointer’ 304 counts the odd addresses such as 1,3,5 etc and the ‘Even Read Pointer’ 305 counts the even address such as 0,2,4, etc.

Odd Read pointer circuit 304 forces “0×01” on the “Odd Read Address’ bus when the ‘read reset’ signal is activated. The contents of the bus “Next Read Address” are assigned to “Odd Read Address” by the “Odd Read Pointer” 304 circuit, only when ‘read reset’ is inactive, ‘odd pointer update’ is ‘1’ and there is a rising edge on read clock. The current contents of the ‘odd read address’ are not changed when ‘odd pointer update’ is at logic ‘0’.

Even Read pointer circuit 305 forces 0×00 on the ‘even read address’ bus when the ‘read reset’ signal is activated. The contents of the ‘next read address’ bus are assigned to ‘Even read address’ by the even read pointer 305 circuit, only when read reset is inactive, even pointer update is ‘1’ and rising edge on read clock. The current contents of the ‘Even read address’ are not changed when even pointer update is at logic ‘0’.

The Current read pointer circuit 308 generates current read address of the FIFO from which the data is accessed. The current read address is provided to the FIFO status circuit 309 along with the write address bus to generate FIFO status signals like full, empty, half full etc. The current read address is also provided to adder 307. Adder 307 generates the next read address by incrementing the contents of the current read address bus and outputs it on the ‘next read address’ bus. The contents of the ‘current read address’ bus are forced to 0×00 by the current read pointer circuit 308 when read reset is active. The next read address is generated when Read reset is inactive, read enable is at logic ‘1’ and there is a rising edge on the read clock

The read process is coordinated by the Finite state machine ‘FSM’ 310. The FSM 310 has two states viz., Odd and Even. When the Read reset is active, the FSM goes to ‘Even’ state. It toggles the state when Read reset is inactive, read enable is high and a rising edge occurs on the Read clock. The ‘Data Out Control’ is at logic ‘0’ when the FSM is in even state, while it is at logic ‘1’ when FSM is in odd state. The Even pointer Update is at logic ‘1’ when FSM is in Even state and Read enable at logic ‘1’. The odd pointer update is at logic ‘1’ when FSM is in Odd state and read enable at logic ‘1’

FIG. 4 shows a timing diagram illustrating the operation of the present invention. Initially, the read reset is inactivated at time T0. The initializations would have already taken place. The contents of different buses at time T0 are as follows.

Current read address to 0×00

State machine to Even state

Even read address to 0×00

Odd read address to 0×01

Next pointer=0×02 (current read address +2)

Data out control to ‘0’

Even data out is data contained in the FIFO element D0

Odd data out is data contained in the FIFO element D1

Read data out contains data D0.

At Time T1

The read enable goes to logic ‘1’, the ‘Even pointer update’ signal also goes to logic ‘1’. The contents of the buses are not updated since there is no rising read clock edge.

At Time T2

A rising read clock edge is present when read enable is at logic ‘1’. The contents of different buses are changed as follows

Current read address to 0×01

State machine to Odd state

Even read address to 0×02

Odd read address remains unchanged at 0×01

Next pointer=0×03 (current read address+2)

Data out control to ‘1’

Odd pointer update is at ‘1’

Even pointer update is at ‘0’

Even data out is data contained in the FIFO element D2

Odd data out remains unchanged and contains the data contained in the FIFO element D1

Read Data out contains data D1

In the absence of the current architecture, at time T2 following events occur: the current read pointer is updated (to 0×01), the updated value is decoded and the contents of the selected data element (D1) are assigned to data out. This process consumes time, affecting the access time of the FIFO. The total time required for the word access includes the time required to decode logic of the address, AND-OR logic required to force the contents of the selected FIFO element on the data out bus and CP to Q delay of the flip flops in the counter. However, the present invention reduces the overall access time by providing a method of look ahead reading that is implemented by fetching the next word from the FIFO and assigning it to the other data out bus (Even data out or Odd data out), the contents of which are not used at the current instant. This scheme gives a timing advantage of 2 read clock cycles for reading data from the FIFO. Therefore, the proposed architecture is able to avoid any latency over head. Furthermore, since the state machine is implemented using a single D-flip flop, the time required for word access with the current architecture is only the CP to Q delay of the flip flop in the state machine plus the MUX delay—which is significantly smaller than earlier.

The events occurring at times T3, T4, T5, T6, T7 and T8 represented in the timing diagram can be explained similarly.

The description of the present invention has been presented for purposes of illustration and is not intended to be exhaustive or limited to the invention in the form disclosed. Many modifications and variations will be apparent to those of ordinary skill in the art.

All of the above U.S. patents, U.S. patent application publications, U.S. patent applications, foreign patents, foreign patent applications and non-patent publications referred to in this specification and/or listed in the Application Data Sheet, are incorporated herein by reference, in their entirety.

From the foregoing it will be appreciated that, although specific embodiments of the invention have been described herein for purposes of illustration, various modifications may be made without deviating from the spirit and scope of the invention. Accordingly, the invention is not limited except as by the appended claims and the equivalents thereof.

We claim:

1. A FIFO buffer providing reduced access times without introducing any latency overhead, comprising:
FIFO means capable of storing ‘n’ data words, each ‘m’ bits wide, having an ‘m’ bit wide data input terminal;
read data selection means connected to data output terminals of the FIFO means and having two data output terminals providing simultaneous access to a selected storage location;
odd read pointer generating means for providing the selection input to the data selection means for selecting data at an odd read address;
even read pointer generating means for providing the selection input to the data selection means for selecting data at an even read address;
multiplexing means coupled to each of the two data output terminals of the read data selection means for selecting one of the outputs of the read data selection means as the final output of the FIFO; and
state controlling means coupled to the multiplexing means for controlling the selection of the final FIFO output and to the odd and even read pointer generating means.

2. The improved FIFO buffer of claim 1, further comprising FIFO status providing means coupled to a selected read pointer means for generating FIFO status signals.

3. The improved FIFO buffer of claim 1, further comprising adder means coupled to the selected read pointer generating means to increment the read address for generating the next read address.

4. The improved FIFO buffer of claim 1 wherein said state maintaining means can have two states namely, odd and even.

5. A method for reducing the access times of a FIFO buffer without introducing latency overhead, comprising the steps of:
providing a FIFO capable of storing ‘n’ data words, each ‘m’ bits wide, having an ‘m’ bit wide data input terminal;
connecting a read data selector to an output of the FIFO and providing simultaneous access to a selected storage location at an odd address and a selected storage location at an even address;
providing selection inputs to the read data selector for selecting an odd read address and an even read address;
multiplexing the output of the read data selector to enable selection of a desired one of the outputs of the read data selector as the final output of the FIFO; and
controlling the state of the FIFO to select one of the multiplexer output as the final output of the FIFO and to control the selection input to the read data selector for selecting an odd read address and an even read address.

6. The method of claim 5, further comprising generating FIFO status signals.

7. The method of claim 5, further comprising generating the next read address by incrementing the current read address.

8. The method of claim 5 wherein said state can be odd or even.

9. A synchronous FIFO buffer, comprising:
a FIFO circuit configured to receive, store, and output data;
a data select circuit coupled to the FIFO circuit to receive data from the FIFO circuit and having a first data output for outputting even data and a second data output for outputting odd data;
a multiplexer circuit coupled to the first and second data outputs of the data select circuit and having a control input and a read data output;
a finite state machine having an output coupled to the control input of the multiplexer circuit, the finite state machine configured to generate a control signal to control the output of the multiplexer circuit; and
a pointer circuit coupled to the finite state machine and configured to generate a read address that is output to the data select circuit.

10. The FIFO circuit of claim 9, wherein the data select circuit is configured to receive a next word from the FIFO circuit and assign it to one of the first data output and the second data output that is not in current use.

11. The FIFO buffer of claim 9, wherein the finite state machine comprises a single D-flip-flop.

12. The FIFO buffer of claim 9, wherein the finite state machine is configured to maintain two states, an odd state and an even state.

13. The FIFO buffer of claim 9, wherein the pointer circuit comprises an odd read pointer circuit and an even read pointer circuit, each coupled to the data select circuit and configured to select an odd read address and an even read address, respectively.

14. A FIFO buffer circuit, comprising: a FIFO circuit configured to receive, store, and output words to a first data bus and a second data bus, and control means coupled to the FIFO circuit and the first and second data outputs and configured to fetch a next word from the FIFO and assign it to one of the first data output and the second data output that is not currently in use.

15. The FIFO buffer of claim 14, wherein the control means comprise a finite state machine coupled to a multiplexer, the multiplexer having the first data output and the second data output as inputs and a read data output as an output.

16. The FIFO buffer of claim 15, wherein the finite state machine comprises a D-flip-flop.

17. A method for reducing access time to a FIFO buffer, comprising:
fetching a next word from a FIFO circuit and assigning it to one of a first data out bus and a second data out bus that is not currently in use.

18. A method for providing access to a FIFO buffer, comprising:
providing simultaneous access to a selected storage location at an odd address and a selected storage location at an even address from an output of a FIFO circuit;
providing selection inputs to a read data selector for selecting an odd read address and an even read address;
multiplexing an output of the read data selector to enable selection of a desired one of the outputs of the read data selector as the final output of the FIFO circuit; and
controlling the state of the FIFO to select one of the multiplexer output as the final output of the FIFO and to control the selection input to the read data selector for selecting an odd read address and an even read address.

19. The method of claim 18, comprising controlling the state of the FIFO with a finite state machine configured to have two states, an odd state and an even state.

20. The method of claim 19, further comprising generating a next read address by incrementing a current read address.
